(19) United States
(12) Patent Application Publication
(10) Pub. No.: US 2002/0168027 A1
(43) Pub. Date: Nov. 14, 2002

(54) Ever-ad radio

(76) Inventors: Armando M. Diaz, Miami, FL (US); Jose M. Diaz, Miami, FL (US)

Correspondence Address: Richard M. Saccocio, Attorney for Applicant(s), Richard M. Saccocio, P.A., 100 S.E. 12th Street, Ft. Lauderdale, FL, 33316, US

(21) Appl. No.: 10/074,319

(22) Filed: Feb. 12, 2002

Related U.S. Application Data
(60) Provisional application No. 60/267,906, filed on Feb. 12, 2001.

(51) Int. Cl. H03K 9/00

(52) U.S. Cl. 375/316

(57) ABSTRACT

A radio includes storage and playback circuitry that interrupts and replaces a regular-programmed commercial with a sponsor's own advertisement or message. The sponsor company has the choice of using a series of different advertisements in place of a single advertisement that is repeated over and over, how long to play the advertisement, and which time periods of the day the advertisement will be played. The radio may or may not be equipped with an RDS separator.

CROSS REFERENCE TO REALTED APPLICATIONS

This application is related to provisional application Serial No. 60/267,906, filed on Feb. 12, 2001.

### BACKGROUND OF THE INVENTION

1. Field of the Invention

This invention relates in general to the field of electronic devices adapted to be used to provide specialty advertisements of a sponsoring business without the costs associated with regular commercial advertising.

2. Description of the Prior Art

In order for a business to be successful, it is fundamental that the monies received from sales or services must exceed the monies spent to provide the sales or services. One way that a business sells its products or services is by advertising. Generally, but not always, the more monies that are spent on advertising, the more the product or service will be purchased. Moreover, it is generally accepted by most businesses that some form of advertising is necessary to the profitability of the business.

The primary goal of advertising is to maximize its effectiveness while minimizing its costs. This goal, however, is difficult to achieve. One reason is because of the large numbers of different media where the advertisements can be placed, for example, radio, television, newspapers, trade magazines, news magazines, flyers, particular interest magazines, the Internet, etc. Another reason is that the cost of placing an advertisement usually varies with the number of people reached by the particular media and not necessarily by those persons who would be interested in the commodity being advertised. These are just some of the problems encountered by businesses in an attempt to maximize the effectiveness of its advertising budget. There are obviously many other reasons.

There also exist some negative aspects of regular commercial advertising. Too much and non-varied advertising can have a reverse effect on potential buyers. Often the particular media determines the time intervals between advertisements. This causes the same advertisement to sometimes appear twice during the same block of advertising time (commercial breaks).

It would, therefore, be most desirable for a business to be able to control how often and for how long its advertisements are directed to potential purchasers, as well as to be able to direct the advertisement to a particular target group rather than the public at large. The present invention achieves these highly desirable considerations.

The above-stated objects as well as other objects which, although not specifically stated, but are intended to be included within the scope of the present invention, are accomplished by the present invention and will become apparent from the hereinafter set forth Detailed Description of the Invention, and the Drawings appended herewith.

### SUMMARY OF THE INVENTION

The present invention accomplishes the above-stated objectives as well as others, as may be determined by a fair reading and interpretation of the entire specification herein.

The Ever-Ad radio product is designed as a direct advertising tool for a wide range of businesses and their products, and is capable of reaching a particular target group either locally or nationally. It is a very flexible advertising tool, which can be directly controlled by the business itself.

The Ever-Ad invention comprises a radio, designed as a give-away product which includes special circuitry that interrupts and replaces a regular programmed commercial with a sponsor's own advertisement. The sponsor company has the choice of using a series of different advertisements in place of a single advertisement that is repeated over and over. The sponsor company has the choice of how long to broadcast its advertisement. The sponsor company has the choice as to which time periods of the day its advertisement will be broadcasted. Moreover, and extremely important, is that the sponsor company's cost of advertising is exceptionally minimized and there is no need to broadcast the messages.

### BRIEF DESCRIPTION OF THE DRAWINGS

Various other objects, advantages, and features of the invention will become apparent to those skilled in the art from the following discussion taken in conjunction with the following drawings, in which:

FIG. 1 is a block diagram of the components of a radio;

FIG. 2 is a block diagram of the components of a radio adapted to receive RDS signals;

FIG. 3 is a block diagram of the components of a playback portion of a radio not equipped to receive RDS signals;

FIG. 4 is a block diagram of the components of a playback portion of a radio that is equipped to receive RDS signals; and,

FIG. 5 comprises a flow chart illustrating the operational sequence of a two message Ever-Ad radio.

### DETAILED DESCRIPTION OF THE PREFERRED EMBODIMENTS

As required, detailed embodiments of the present invention are disclosed herein; however, it is to be understood that the disclosed embodiments are merely exemplary of the invention, which may be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure. Further, the terms and phrases used herein are not intended to be limiting; but rather, to provide an understandable description of the invention.

Reference is now made to the drawings, wherein like characteristics and features of the present invention shown in the various figures are designated by the same reference numerals.

A standard industry-wide feature of radio broadcasting is the Radio Data System (RDS). RDS is a digital signal that is incorporated within the plurality of signals transmitted by a radio station during its broadcasting. RDS signals include such data as the station's call letters, the station's name, the name of a song (if one is being played), the name of the artist, the name of the show, the name of the sponsor, weather reports, traffic reports, the name of the show's host, and other like bits of information.

At the present time, not all radio broadcasting stations are capable of transmitting RDS signals. Therefore, two versions of the Ever-Ad radio will be hereinafter described.

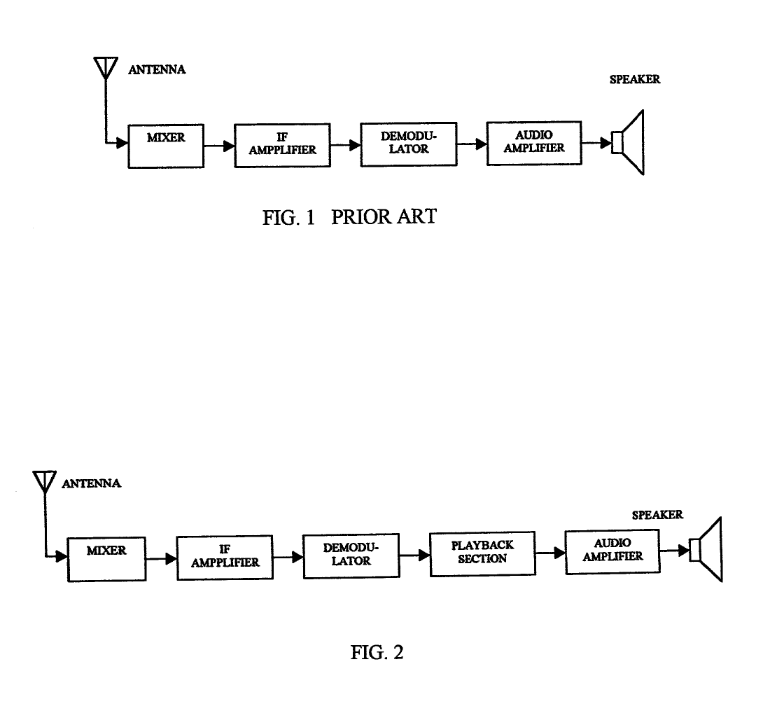

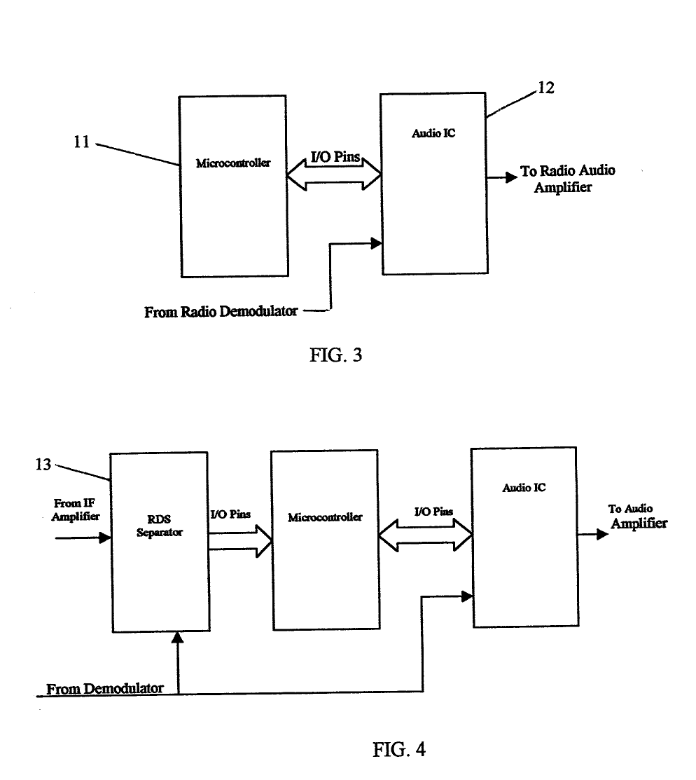

A standard radio receiver (non-RDS equipped) includes an antenna for receiving a signal, a mixer, an inter-medium frequency amplifier (I.F. amplifier), a demodulator, an audio amplifier, and a speaker as generally shown in FIG. 1. The invention herein utilizes a storage and playback section inserted between the demodulator and the audio amplifier, as shown in FIG. 2. As more fully explained hereinafter, the storage and playback portion includes an audio information storage and playback circuit.

FIG. 3 is a block diagram illustrating the storage and playback circuitry as applied to a radio not equipped with RDS. A microcontroller 11 serves as a timing and control device. An audio information storage integrated circuit 12 functions as an audio storage and signal processing device. It is within the audio information storage circuit 12 that one or more prerecorded messages are stored. The microcontroller 11 directs which prerecorded message is to be played and when it is to be played. The microcontroller 11 can comprise any 8-bit reduced instruction set computer (RISC) having as little as 512 bytes of program memory and eight input/output pins, such as a microchip PIC16C54. The storage and playback device 12 is selected depending upon the content of the message or messages to be stored. An audio IC such as an ISD2532 or an ISD25120 chip can be used for this purpose.

FIG. 4 is a block diagram of the storage and playback circuitry as applied to a radio equipped with RDS. As is seen, an additional device, namely, an RDS separator 13, is used with a microcontroller 11 and a storage and playback device 12. The RDS signals are inaudible digital signals that are mixed together with the audible signals. The RDS separator 13 separates the RDS signals from the mixed signals and feeds the RDS signals to the micro controller 11 for decoding. A Phillips SAA6855 can be used for this purpose. The micro controller 11 and the storage and playback device 12 again function as described with regard to FIG. 3.

With either the non-RDS radio of FIG. 3 or the RDS equipped radio of FIG. 4, it is necessary that one or more prerecorded messages be stored within the storage and playback device 12. The length of the prerecorded message or messages is variable, depending upon the capabilities of the chip or chips 12 being used. Typically, however, a single message can last from, for example, 20 to 30 seconds; the number of different messages can be between, for example, 1 to 4 messages. Of course, these are just examples of prerecorded messages that can be used for advertising and are not intended to be limiting. It is to be noted that the messages need not be restricted to advertisements, for example, religious or political messages can be recorded and played back.

If the radio station does not have RDS capability, the prerecorded message will interrupt the regular broadcasting at preprogrammed intervals, for example, twenty minutes, thirty minutes, one hour, etc. A lead-in announcement can be used for the purpose of informing the listener that the interruption is deliberate and not to be confused with the regular program. If there is a plurality of prerecorded messages, they can be played in any preprogrammed or random sequence in accordance with the instructions programmed in the audio IC 12.

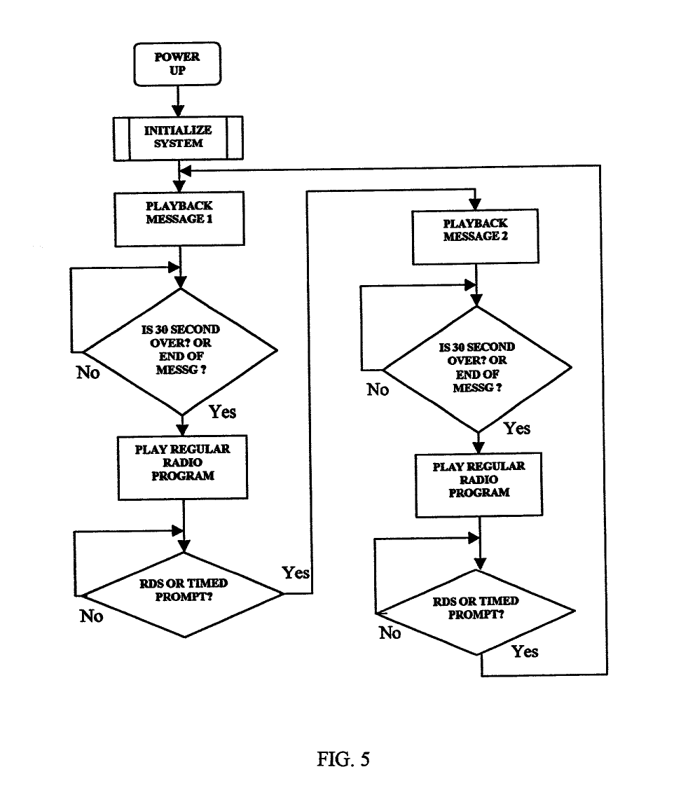

If the radio and the station tuned to by the listener has RDS capabilities, the arrangement of FIG. 4 provides for smooth interruptions of the regular commercial advertisements and the substitution of the broadcasted commercial with the prerecorded message. In this regard, a host program is loaded into the microcontroller 11. Specifically, the host program detects the broadcasting of a regular commercial message, tracks the radio tone and the playback time, and makes the switching actions accordingly. FIG. 5 comprises a flow chart illustrating the sequence of such a process using a two message input.

In use, a person or organization determines if his or its message is to be used with a radio having or not having an RDS. Then the message to be played is determined along with the frequency, length of time, at what hour in the day, on which day or days, the message is to be played as well as any other particulars regarding the message. The message particulars are then programmed into the micro controller 11, and the storage and playback circuit 12. One or more radios are provided with the programmed micro controller 11 and the audio IC 12 and distributed to one or more persons. The persons having the inventive radio then play the radio 10 as they would any other radio. The prerecorded and stored message or messages will then be played back in accordance with the programmed particulars of the message or messages.

While the invention has been described, disclosed, illustrated and shown in certain terms or certain embodiments or modifications which it has assumed in practice, the scope of the invention is not intended to be nor should it be deemed to be limited thereby and such other modifications or embodiments as may be suggested by the teachings herein are particularly reserved

We claim as our invention:

1. A method for providing a radio with prerecorded messages for programmed playback comprising the steps of
programming a storage and playback circuitry with a message and message particulars, said circuitry comprising a micro controller and an audio integrated circuit,
connecting said storage and playback circuitry between a demodulator and an audio amplifier of a radio, , and
inputting a signal from the demodulator to the audio integrated circuit.

2. The method of claim 1, including the steps of
connecting an RDS separator to the radio such that signals from an IF amplifier within the radio and said demodulator are input to said RDS separator, and
connecting said RDS separator to said micro controller.

3. Apparatus adapted to be connected to a radio comprising a storage and playback circuit connected between a demodulator and an audio amplifier of said radio.

4. The apparatus of claim 3, wherein said storage and playback circuit comprises a micro controller.

5. The apparatus of claim 4, wherein said storage and playback circuit includes an audio integrated circuit.

6. The apparatus of claim 5, wherein said radio includes an RDS separator connected to said micro controller, said micro controller being connected to said audio integrated circuit.

7. The apparatus of claim 6, wherein said RDS separator receive a signal from an IF amplifier and from said demodulator, and said audio integrated circuit receives a signal from said demodulator.
